(19) United States
(12) Patent Application Publication
(10) Pub. No.: US 2006/0062912 A1
(43) Pub. Date: Mar. 23, 2006

(54) Bond coat for a thermal barrier coating system and related method thereof

(76) Inventors: David J Wortman, Hamilton, OH (US); Haydn N.G Wadley, Keswick, VA (US)

Correspondence Address: UNIVERSITY OF VIRGINIA PATENT FOUNDATION, 250 WEST MAIN STREET, SUITE 300, CHARLOTTESVILLE, VA, 22902, US

(21) Appl. No.: 10/535,364

(22) PCT Filed: Nov. 21, 2003
(86) PCT No.: PCT/US03/37485

§ 371 Date: May 18, 2005

Related U.S. Application Data
(60) Provisional application No. 60/428,523, filed on Nov. 21, 2002.

(51) Int. Cl. C23C 16/00

(52) U.S. Cl. 427/248.1; 118/715; 118/726

(57) ABSTRACT

Method and Apparatus for efficiently applying a bond coat and related coating systems to a surface that can survive the thermal gradient that is encountered in very high temperature, high heat flux environments such as a rocket engine. An apparatus for efficiently applying coating systems using a vapor or cluster deposition technique such as a directed vapor deposition (DVD) approach, and more particularly providing a thermal barrier coating (TBC) system applications with very high temperature utility in cither oxidizing or non-oxidizing conditions.

### CROSS-REFERENCE TO RELATED APPLICATIONS

The present invention claims priority from U.S. Provisional Application Ser. No. 60/428,523 filed Nov. 21, 2002, entitled “Thermal Barrier Coating Systems for Rocket Engine Applications and Related Method thereof,” the entire disclosure of which is hereby incorporated by reference herein.

The present application is also related to International Application No. PCT/US03/36035, filed Nov. 12, 2003, Attorney Docket No. 00837-02, entitled “Extremely Strain Tolerant Thermal Protection Coating and Related Method and Apparatus Thereof,” of which is assigned to the present assignee and is hereby incorporated by reference herein in its entirety.

The present application is also related to International Application No. PCT/US03/23111, filed Jul. 24, 2003, entitled “Method and Apparatus for Dispersion Strengthened Bond Coats for Thermal Barrier Coatings,” of which is assigned to the present assignee and is hereby incorporated by reference herein in its entirety.

The present application is also related to International Application No. PCT/US02/28654, filed Sep. 10, 2002, entitled “Method and Apparatus for Application of Metallic Alloy Coatings,” of which is assigned to the present assignee and is hereby incorporated by reference herein in its entirety.

### GOVERNMENT SUPPORT

This invention was made with government support under the Air Force Grant No. GI 11083 and Project No. 117237. The government has certain rights in the invention.

### BACKGROUND OF THE INVENTION

The present invention thermal barrier coating (TBC) systems comprise metallic bond coats and a thermal insulating layer may be used in future rocket engines and related components, such as combustor liners, to protect the structure from the very high temperature combustion gasses. The environment is such that the bond coat may be exposed to temperatures of about 1,500° C. or more. This is much hotter than in current TBC systems used on gas turbine engine components, which may be about. 1,100-1,200° C. or less. In a rocket engine, the ceramic TBC layer could be expected to operate at temperatures up to about 3,300° C. or more. Many factors must be considered in selecting a bond coat-ceramic coating system for a rocket combustor. They include the metallic alloy to which they are applied, the thermal/mechanical loading, the chemical environment (oxidation/reduction), etc. An important problem, for example, that must be addressed is overheating of the bond coat in case of a local spall of the TBC layer. In this scenario, the bond coat surface temperature could increase to over about 2,000° C.

In gas turbine TBCs, long life in the oxidizing environment of the gas turbine is a requirement. Thus, MCrAlY and PtAl type bond coats that are used as part of these TBCs form a slow growing alumina scale under application (hot oxidizing) that impedes further oxidation and also provides good adhesion to the ceramic part of the TBC system. The oxide has been called a thermally grown oxide (TGO). However, in a rocket engine, the need for oxidation resistance and formation of a TGO may not always be critical since reducing conditions sometimes prevail for most or all of the duty cycle. In that case the more critical need will be high temperature stability and melting point. The conventional MCrAlY and PtAl bond coats on nickel alloys melt at or below about 1,300 C and are unsatisfactory for rocket engine applications.

The present invention provides a method and an apparatus for efficiently applying coating systems using a vapor or cluster deposition technique such as a directed vapor deposition (DVD) approach, and more particularly providing a thermal barrier coating (TBC) system applications with very high temperature utility in either oxidizing or non-oxidizing conditions. The present invention can survive the very large thermal gradient that is encountered in high temperature, very high heat flux environments such as, but not limited thereto, to the combustor liner, combustor throat, or exhaust nozzle of a rocket engine.

These and other objects, along with advantages and features of the invention enclosed herein, will be made more apparent from the description, drawings, and claims that follow.

### SUMMARY OF THE INVENTION

The present invention provides a method and an apparatus for efficiently applying a bond coat and related coating systems to a surface that can survive the thermal gradient that is encountered in very high temperature, high heat flux environments such as a rocket engine. To overcome the limitations incurred by conventional TBC system deposition methods, exemplary embodiments use an electron or other energetic, beam directed vapor deposition (DVD) technique to evaporate and deposit the related coating systems. The present invention comprises a TBC system for rocket engine combustors or similar applications with very high temperature capability in limited oxidation or non-oxidation conditions. High temperature bond coat materials are provided, such as Fe, Ni, Cr, Pt, Ir, Ti, Zr, Ta, Nb, and W.

In addition, thermal insulating layer materials are implemented with the present invention bond coats. The thermal insulating layer applications are provided in commonly owned International Application No. PCT/US03/36035, filed Nov. 12, 2003, Attorney Docket No. 00837-02, entitled “Extremely Strain Tolerant Thermal Protection Coating and Related Method and Apparatus Thereof.” For instance, these thermal insulating layers comprise refractory carbide materials and/or any other ceramic whose melting temperature is greater than, for example, about 2,000° C. In some instances, thermodynamic compatibility is not as critical of an issue since the coatings are expected to experience no more than about 100-1,000 minutes of high temperature exposure. Moreover, it should be appreciated that a variety of deposition techniques, methods, and apparatus can be used to evaporate and deposit morphology controlled coating systems of the present invention. Such deposition techniques include, but not limited thereto, the following chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, cluster deposition, and the like.

In one modality, the present invention DVD technique uses the combination of an energetic beam source (e.g., electron or high intensity laser, beam gun) (capable of evaporating material in a low vacuum environment) and a combined inert gas/reactive gas carrier jet of controlled composition to create engineering films. In this system, the vaporized material can be entrained in the carrier gas jet and deposited onto the substrate at a high rate and with high materials utilization efficiency. The velocity and flux of the gas atoms entering the chamber, the nozzle parameters, and the operating chamber pressure can all be significantly varied, facilitating wide processing condition variation and allowing for improved control over the properties of the deposited layer. In particular, under some (higher pressure/high evaporation rate) processing conditions, nanoscopic particles can be reactively formed in the vapor and incorporated in the coating.

In another aspect of the present invention, by employing plasma enhancement, multisource crucibles and appropriate process condition control, the morphology, composition, dispersoid size and concentration, the bondcoat grain size and porosity of deposited layers are all controlled. In a second modality, the present invention uses a different evaporation source to reactively create dispersoids which are then entrained in the vapor plume used for depositing the coating.

In a third modality, dispersoids are created before deposition and are entrained in the noble gas stream and used to transport the bond coat vapor to the component surface. In modalities one, two, and three a plasma may also be used to control the bond coat structure. In all modalities, the result is a low cost deposition approach for applying bond coats which can have compositions and dispersoids distributions which are difficult to deposit using other conventional approaches.

Alternatively, the dispersoid distributions may be optional and therefore omitted in part or entirely from the process.

The DVD apparatus and method comprises a vacuum chamber, energetic beam source (e.g., beam gun), evaporation crucible(s), and inert/reactive gas jet. In addition, a plasma can be created. A substrate bias system capable of applying a DC or alternating potential to at least one of the substrates can then be used for plasma assisted deposition. The electron beam impinges on at least one of the vapor flux sources contained in the crucible. The resulting vapor is entrained in at least one of the carrier gas streams. Hollow cathode arc plasma activation source may or may not be used to ionize at least one of the generated vapor flux and at least one of the carrier gas stream. The ionized or non-ionized generated vapor flux and carrier gas stream are attracted to the substrate surface by allowing a self-bias of the ionized gas and vapor stream or the potential to pull the ionized stream to the substrate.

In an alternative embodiment an end-hall ion source is modified to function as the evaporation and plasma creating system.

It should be appreciated that additional coating layers can be inserted or added between or adjacent to layers shown, described and/or illustrated herein.

An embodiment provides a method for forming a thermal barrier coating system. The method comprising: presenting at least one substrate; depositing at least one of Ti, Ti alloy, or any combination thereof to form a bond coat on at least a portion of at least one the substrate; and depositing at least one of zirconia, zirconia alloy, TiN, TiC, TiN alloy, TiC alloy,or any combination thereof to form a deposition of a thermal-insulating layer on the bond coat.

An embodiment provides a method for forming a thermal barrier coating system. The method comprising: presenting at least one substrate; depositing at least one of Zr, Zr Alloy, or combination thereof to form a bond coat on at least a portion of at least one the substrate; and depositing at least one of ZrC or ZrC alloys, or any combination thereof to form a deposition of a thermal-insulating layer on the bond coat.

An embodiment provides a method for forming a thermal barrier coating system. The method comprising: presenting at least one substrate; depositing at least one of Nb, Nb alloy, Ta, Ta alloy or any combination thereof to form a bond coat on at least a portion of at least one the substrate; and depositing at least one of as oxide or a carbide or any combination thereof to form a thermal-insulating layer on the bond coat.

An embodiment provides a method for forming a thermal barrier coating system. The method comprising: presenting at least one substrate; depositing at least one of stainless steel, composite-of stainless steel, or alloy of stainless steel, or any combination thereof to form a bond coat on at least a portion of at least one the substrate; and depositing a thermal-insulating layer on the bond coat.

An embodiment provides a method for forming a thermal barrier coating system. The method comprising: presenting at least one substrate; depositing at least one intermetallic to form a bond coat on at least a portion of at least one the; and depositing a thermal-insulating layer on the bond coat.

An embodiment provides a deposition apparatus for forming a thermal barrier coating system. The apparatus comprising: a housing, wherein at least one substrate is presented in the housing; a deposition means for depositing at least one of Ti, Ti alloy, or any combination thereof to form a bond coat on at least a portion of at least one the substrate; and the deposition means for depositing at least one of zirconia, zirconia alloy, TiN, TiC, TiN alloy, TiC or any combination thereof to form a deposition of a thermal-insulating layer on the bond coat.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam, wherein the energetic beam(s): impinges at least one the evaporant source with at least one the energetic beam in the chamber to generate a bond coat evaporated vapor flux, the at least one evaporant source comprising at least one of Ti, Ti alloy, or any combination thereof to form, and deflects at least one of the generated bond coat evaporated vapor flux by at least one of the carrier gas stream, wherein the bond coat evaporated vapor flux at least partially coats at least one of the substrates to form the bond coat. The same or other energetic beam(s): impinges at least one of the evaporant source with at least one the energetic beam in the chamber to generate a thermal-insulating layer evaporated vapor flux, wherein the evaporant source for generating the thermal-insulating layer comprise at least one of zirconia, zirconia alloy, TiN, TiC, TiN alloy, TiC or combination thereof, and deflects at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat.

An embodiment provides a deposition apparatus for forming a thermal barrier coating system. The apparatus comprising: a housing, wherein at least one substrate is presented in the housing; a deposition means, the deposition means for depositing at least one of Zr, Zr alloy, or combination thereof to form a bond coat on at least a portion of at least one the substrate; and the deposition means for depositing at least one of ZrC, ZrC alloy, or any combination thereof to form a deposition of a thermal-insulating layer on the bond coat.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam. The energetic beam(s); impinges at least one the evaporant source with at least one the energetic beam in the chamber to generate a bond coat evaporated vapor flux, the at least one evaporant source comprising at least one of Zr, Zr alloy, or any combination thereof, and deflects at least one of the generated bond coat evaporated vapor flux by at least one of the carrier gas stream, wherein the bond coat evaporated vapor flux at least partially coats at least one of the substrates to form the bond coat. The same or other energetic beam(s): impinges at least one of the evaporant source with at least one the energetic beam in the chamber to generate a thermal-insulating layer evaporated vapor flux, wherein the evaporant source for generating the thermal-insulating layer comprise at least one of ZrC, ZrC alloys, or any combination thereof or any of their alloys, and deflects at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat.

An embodiment provides a deposition apparatus for forming a thermal barrier coating system. The apparatus comprising: a depositing means, the depositing means for depositing a at least one of Nb, Nb alloy, Ta, Ta alloy or any combination thereof to form bond coat on at least a portion of at least one the substrate; and the depositing means for depositing at least one of an oxide or a carbide to form a thermal-insulating layer.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam. The energetic beam(s): impinges at least one the evaporant source with at least one the energetic beam in the chamber to generate a bond coat evaporated vapor flux, the at least one evaporant source comprising at least one of Nb, Nb alloy, Ta, Ta alloy or any combination thereof, and deflects at least one of the generated bond coat evaporated vapor flux by at least one of the carrier gas stream, wherein the bond coat evaporated vapor flux at least partially coats at least one of the substrates to form the bond coat. The same or other energetic beam(s): impinges at least one of the evaporant source with at least one the energetic beam in the chamber to generate a thermal-insulating layer evaporated vapor flux, wherein the evaporant source for generating the thermal-insulating layer comprises at least one of an oxide or carbide, and deflects at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat.

An embodiment provides a deposition apparatus for forming a thermal barrier coating system. The apparatus comprising: a depositing means, the depositing means for depositing at least one of stainless steel, composite of stainless steel, or alloy of stainless steel, or any combination thereof to form a bond coat on at least a portion of at least one the substrate; and the depositing means for depositing a thermal-insulating layer.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam. The energetic beam(s): impinges at least one the evaporant source with at least one the energetic beam in the chamber to generate a bond coat evaporated vapor flux, wherein the evaporant source comprises at least one of stainless steel, composite of stainless steel, or alloy of stainless steel, or any combination thereof, and deflects at least one of the generated bond coat evaporated vapor flux by at least one of the carrier gas stream, wherein the bond coat evaporated vapor flux at least partially coats at least one of the substrates to form the bond coat. The same or other energetic beam(s): impinges at least one of the evaporant source with at least one the energetic beam in the chamber to generate a thermal-insulating layer evaporated vapor flux, and deflects at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat.

An embodiment provides a deposition apparatus for forming a thermal barrier coating system, the apparatus comprising: a depositing means, the depositing means for depositing at least one of intermetallic; and the depositing means for depositing a thermal-insulating layer.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam. The energetic beam(s): impinges at least one the evaporant source with at least one the energetic beam in the chamber to generate a bond coat evaporated vapor flux, wherein the evaporant source comprises at least one intermetallic material, and deflects at least one of the generated bond coat evaporated vapor flux by at least one of the carrier gas stream, wherein the bond coat evaporated vapor flux at least partially coats at least one of the substrates to form the bond coat. The same or other energetic beam(s): impinges at least one of the evaporant source with at least one the energetic beam in the chamber to generate a thermal-insulating layer evaporated vapor flux, and deflects at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat.

An embodiment provides a coating system on a substrate, wherein the coating system comprises: a bond coat in communication with at least a portion of the substrate, the bond coat comprising least one of Ti, Ti alloy, or any combination thereof; and a thermal-insulating layer in communication with at least a portion of the bond coat, the thermal-insulating layer comprising at least one of zirconia, zirconia alloy, TiN, TiC, TiN alloy, TiC alloy or any combination thereof.

An embodiment provides a coating system on a substrate, wherein the coating system comprises: a bond coat in communication with at least a portion of the substrate, the bond coat comprising least one of Zr, Zr Alloy, or any combination thereof; and a thermal-insulating layer in communication with at least a portion of the bond coat, the thermal-insulating layer comprising at least one of ZrC, ZrC alloys or any combination thereof.

An embodiment provides a coating system on a substrate, wherein the coating system comprises: a bond coat in communication with at least a portion of the substrate, the bond coat comprising least one of Nb, Nb alloy, Ta, Ta alloy, or any combination thereof; and a thermal-insulating layer comprised of at least one of an oxide or a carbide, or combination thereof, in communication with at least a portion of the bond coat.

An embodiment provides a coating system on a substrate, wherein the coating system comprises: a bond coat in communication with at least a portion of the substrate, the bond coat comprising least one of at least one of stainless steel, composite of stainless steel, or alloy of stainless steel, or any combination thereof; and a thermal-insulating layer in communication with at least a portion of the bond coat.

An embodiment provides a coating system on a substrate, wherein the coating system comprising: a bond coat in communication with at least a portion of the substrate, the bond coat comprising intermetallic material; and a thermal-insulating layer in communication with at least a portion of the bond coat.

### BRIEF DESCRIPTION OF THE FIGURES

The foregoing and other objects, features, and advantages of the present invention, as well as the invention itself, will be more fully understood from the following description of preferred embodiments, when read together with the accompanying drawings, in which:

FIGS. 1(A)-(B) are schematic illustrations of a cross-section partial view of the substrate showing a thermal barrier coating system on the substrate in accordance with exemplary embodiments of this invention.

FIG. 2 is a schematic illustration of the directed vapor deposition (DVD) processing system. Included in the process are the ability to evaporate from one or more individual source materials and, optionally, the ability to ionize the evaporated flux using hollow cathode plasma activation.

FIG. 3 is a schematic illustration of the hollow cathode plasma activation unit, optionally, used in the present invention DVD apparatus. The cathode plasma activation device emits low energy electrons that ionize the vapor atoms and carrier gas. By properly biasing the substrate the impact energy of both species can be controlled.

### DETAILED DESCRIPTION OF THE INVENTION

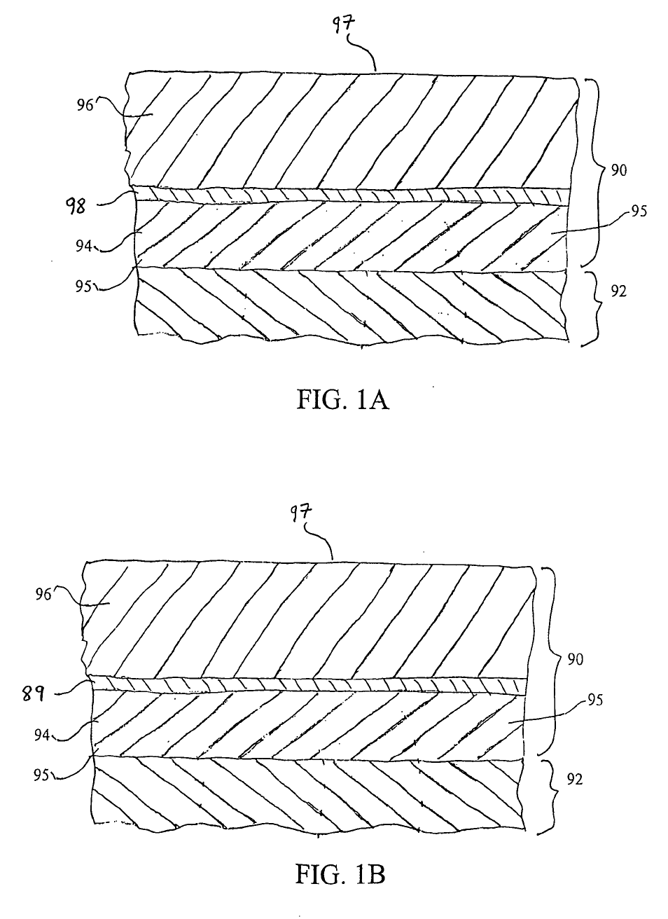

The present invention provides, among other things, TBC systems comprising a higher temperature capable bond coat system that is not necessarily based on formation of an alumina thermally grown oxide (TGO). While conventional bond coat compositions that form alumina TGO have lower melting points than required, for the present invention oxidation protection is not necessarily required under reducing conditions. An embodiment of the present invention TBC system is specifically designed for rocket engine and other related applications, however it may be applicable to any application that sees high temperatures and either non-oxidizing or limited oxidizing conditions. Materials for the bond coat layer may include; but not limited thereto iron (Fe), nickel (Ni), Chronium (Cr), Plantinum (Pt), Iridium (Ir), titanium (Ti), zirconium (Zr), niobium (Nb), tantalum (Ta), and tungsten (W) and their alloys. Functionally layering and or grading of these materials is also provided in various embodiments. Illustrative coatings are schematically shown in FIGS. 1(A)-(B), and shall be discussed in greater detail throughout this document.

The present invention is an improved thermal barrier coating (and related method and system for making the same) which comprises, among other things, a) a substrate typically a nickel base superalloy or copper alloy, b) a bond coat (with or without dispersions for strengthening) and c) a ceramic insulating layer (i.e., thermal insulating layer) or layers on top. Optionally, a dispersion strengthened bond coat would improve coating system life due to greater yield and creep strength, as well as improving the adhesion of the thermally grown oxide (TGO) layer to the bondcoat and enable top coats of preferred morphology to be nucleated.

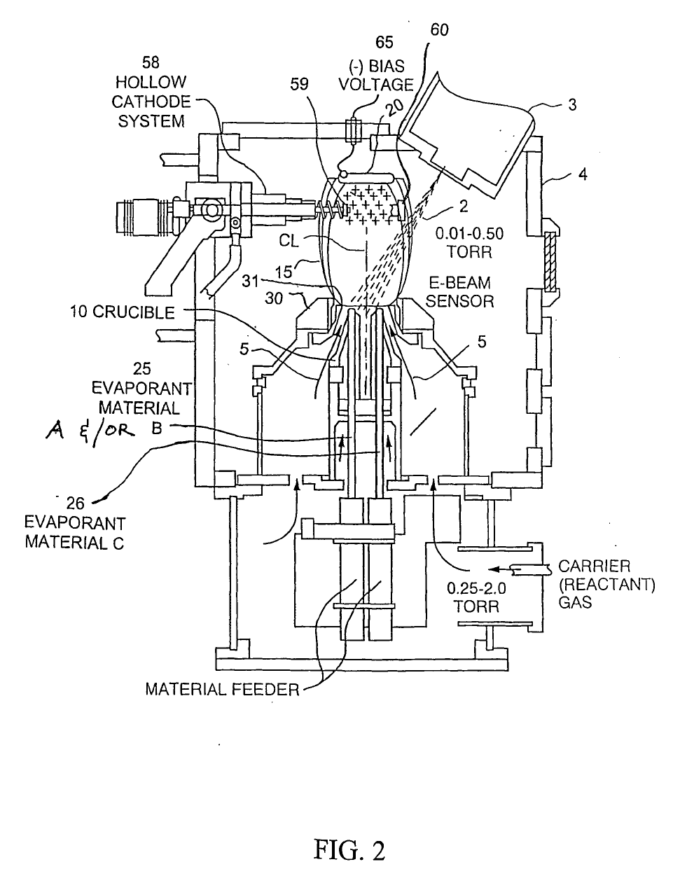

FIG. 2 shows a schematic illustration of the directed vapor deposition (DVD) process. In the DVD, the carrier gas stream 5 is created by a rarefied, inert gas supersonic expansion through a nozzle 30. The speed and flux of the atoms entering the chamber 4, the nozzle parameters, and the operating chamber pressure can all be varied leading to a wide range of accessible processing conditions. As part of the process the supersonic carrier gas stream is maintained by achieving a high upstream pressure (i.e. the gas pressure prior to its entrance into the processing chamber), Pᵤ, and a lower chamber pressure, Pₒ. The ratio of the upstream to downstream pressure along with the size and shape of the nozzle opening 31 controls the speed of the gas entering the chamber 4. The carrier gas molecular weight (compared to that of the vapor) and the- carrier gas speed controls its effectiveness in redirecting the vapor atoms via binary collisions towards the substrate 20. As will be discussed later, alternative embodiments of the present invention process will provide other capabilities to evaporate from two or more individual source rods and the ability to ionize the evaporated flux using hollow cathode plasma activation.

Still referring to FIG. 2, the aforementioned DVD process is schematically shown in FIG. 2, improving the deposition efficiency, increasing the deposition rate, optionally providing coating dispersoids, and enhancing the coating uniformity. As will be discussed later, the hollow cathode system 58 is optional based on desired operations. In an embodiment, the carrier gas 5 is realigned so that it is substantially in-line with the crucible 10. In this alignment, the carrier gas flow is placed completely or substantially around the crucible 10 so that the vapor flux 15 no longer has to be turned 90 degrees towards the substrate 20, but rather can be simply focused onto the substrate located directly above the evaporant source 25 for material A and/or B and evaporant source 26 for material C. For example, material A, B and/or C may include Y, Al, Ni, Pt, Co, Mo, Fe, Zr, Hf, Yb, and/or other reactive elements that form the matrix of the bond coat and, optionally, the ceramic dispersoids throughout the bond coat. Moreover, material A, B and/or C may include higher melting temperature materials, such as refractory metals Molydenum (Mo), Niobium (Nb), Tantalum (Ta), Titanium (Ti), or Tungsten (W), refractory metal alloys (e.g., but not limited thereto, intermetallics based upon these and other metals like Titanium alloys (such as TiAl, TiAl₃)), or carbides (such as TiC, HfC, ZrC, TaC, W2C, SiC), or borides, or any alloys of the aforementioned refractory metals, carbides or borides (and/or other elements as desired and required) that form the matrix of the thermal insulation layer/ceramic layer. Additionally, for materials A, B, and/or C other oxides and nitrides may be suitable, for example, but not limited thereto, BN, MgO and BeO due to their very high temperature capability.

The carrier gas 5 flows substantially parallel with the normal axis, identified as CL. Additionally, as will be discussed later herein, the nozzle 30 has a nozzle gap or opening 32, through which carrier gas 5 flows, is designed such that a more optimal carrier gas speed distribution for focusing the vapor 15 is produced. Also shown is the energetic beam source 3, such as electron beam source, laser source, heat source, ion bombardment source, highly focused incoherent light source, microwave, radio frequency, EMF, or combination thereof, or any energetic beams that break chemical bonds.

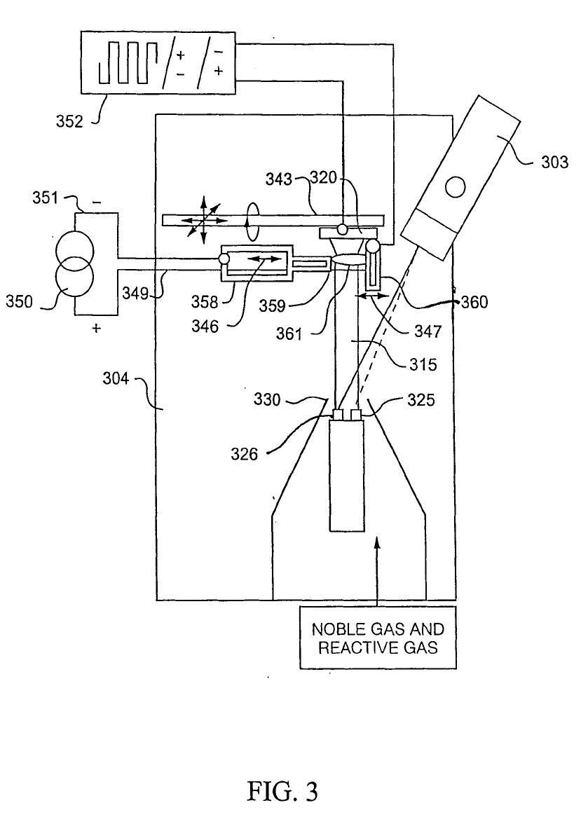

Turning to FIG. 3, the major components of the present invention DVD system including a hollow cathode arc plasma activation and substrate bias supply as schematically shown. The present invention DVD system is comprises a vacuum chamber 304, a first rod feed evaporator 325 (evaporant A & B) and second rod evaporator 326 (evaporant C) that are placed aid heated up to evaporation temperature of evaporant by the electron-beam of an electron gun 303 and provides the vapor for coating of substrates 320. Vaporized evaporant is entrained in the supersonic gas and vapor stream 315 formed by the nozzle 330. The substrate(s) 320 are fixed at a substrate holder 343 which enables shift of the substrate in any independent direction and to be swiveled. For example, the translation motion in the horizontal plan allows the exposed surface areas of the substrate to the vapor stream for defined dwelling times and control of the local coating thickness. The vertical motion can be used to keep constant the distance between plasma and surface for curved substrates. Swivel motion, in coordination with the translation motions, can be used to enable the coating of complete three-dimensional parts or can be used also to change the incidence angle of the vapor particles in the course of layer coating in a defined way for getting distinct layer properties. The hollow cathode (arc source) 358 is placed laterally below substrate holder 343 with a short distance between the cathode orifice 359 and the gas and vapor stream 315. The anode 360 is arranged opposite the cathode orifice 359 (i.e., on an approximate distant side of the stream 315) so that the fast electrons and the plasma discharge 361 crosses the gas and vapor stream 315. The fixtures for the cathode 346 and for the anode 347 provide the ability to adjust the distance of the cathode 358 and the anode 360, thereby influencing the diameter and the shape of gas and vapor stream 315.

The plasma discharge 361 is in close proximity (arranged with short distance) to the surface of the substrate 320 enabling close contact between dense plasma and the substrate surface to be coated. In the vicinity of the evaporation electron-beam from the electron gun 303, the anode power line 349 from the power generator 350 to the anode 360 is arranged closely and in parallel with both the plasma discharge 359 and the cathode power line 351, which runs from the cathode to the power generator 350. Between the substrate 320 and the anode 360, a bias generator 352 is applied that allows for generation of a positive, a negative or a periodically alternating voltage between the substrate 320 and the plasma 361.

In all such cases, the ability to deposit compositionally controlled coatings efficiently, uniformly, at a high rate, with high part throughput, and in a cost-effective manner is desired. Some illustrative examples of deposition systems are provided in the following applications and patents and are co-assigned to the present assignee 1) U.S. Pat. No. 5,534,314, filed Aug. 31, 1994, entitled “Directed Vapor Deposition of Electron Beam Evaporant,” 2) U.S. Pat. No. 5,736,073, filed Jul. 8, 1996, entitled “Production of Nanometer Particles by Directed Vapor Deposition of Electron Beam Evaporant,” 3) U.S. Pat No. 6,478,931 B1, filed Aug. 7, 2000, entitled “Apparatus and Method for Intralayer Modulation of the Material Deposition and Assist Beam and the Multilayer Structure Produced There from,” and corresponding Divisional U.S. application Ser. No. 10/246,018, filed Sep. 18, 2002, 4) International Application No. PCT/US01/16693, filed May 23, 2001 entitled “A process and Apparatus for Plasma Activated Deposition in a Vacuum,” and corresponding U.S. application Ser. No. 10/297,347, filed Nov. 11, 2002, and 5) International Application No. PCT/US02/13639, filed Apr. 30, 2002 entitled “Method and Apparatus for Efficient Application of Substrate Coating;” of which all of these patents and applications are hereby incorporated by reference herein in their entirety.

Other U.S. patents, applications, and Publications that are hereby incorporated by reference herein in their entirety include the following:

1. U.S. Publication No. 2003/0180571 A1 to Singh

2. U.S. Publication No. 2003/0138660 A1 to Darolia et al.

3. U.S. Publication No. 2003/0129378 A1 to Movchan et al.

4. U.S. Publication No. 2003/0129316 A1 to Darolia et al.

5. U.S. Publication No. 2003/0118874 A1 to Murphy

6. U.S. Publication No. 2002/0110698 A1 Singh

7. U.S. Pat. No. 6,630,199 B1 to Austin et al.

8. U.S. Pat. No. 6,585,878 B2 to Stangman et al.

9. U.S. Pat. No. 6,528,118 B2 to Lee et al.

10. U.S. Pat. No. 6,485,845 B1 to Wustman et al.

11. U.S. Pat. No. 6,461,746 B1 to Darolia et al.

12. U.S. Pat. No. 6,455,167 B1 to Rigney et al.

13. U.S. Pat. No. 6,444,331 B2 to Ritter et al.

14. U.S. Pat. No. 6,440,496 B1 to Gupta et al.

15. U.S. Pat. No. 6,436,473 B2 to Darolia et al.

16. U.S. Pat. No. 6,395,343 B1 to Strangman

17. U.S. Pat. No. 6,306,524 B1 to Spitsberg et al.

18. U.S. Pat. No. 6,291,084 B1 to Darolia et al.

19. U.S. Pat. No. 6,273,678 B1 to Darolia

20. U.S. Pat. No. 6,258,467 B1 to Subramanian

21. U.S. Pat. No. 6,255,001 B1 to Darolia

22. U.S. Pat. No. 6,203,927 B1 to Subramanian et al.

23. U.S. Pat. No. 6,168,874 B1 to Gupta et al.

24. U.S. Pat. No. 6,153,313 to Rigney et al.

25. U.S. Pat. No. 6,123,997 to Schaeffer et al.

26. U.S. Pat. No. 6,096,381 to Zheng

27. U.S. Pat. No. 5,712,050 to Goldman et al

28. U.S. Pat. No. 5,498,484 to Duderstadt

29. U.S. Pat. No. 5,419,971 to Skelly et al.

30. U.S. Pat. No. 4,321,311 to Strangman

31. U.S. patent Publication No. 2002/0152961 A1 to Burns

32. U.S. Pat. No. 6,485,844 B1 to Strangman et al.

33. U.S. Pat. No. 6,458,473 B1 to Conner et al.

34. U.S. Pat. No. 6,477,932 B1 to O'Hara et al.

35. U.S. Pat. No. 6,255,001 B1 to Darolia

36. U.S. Pat. No. 6,123,997 to Schaeffer et al.

Turning to FIG. 1(A), FIG. 1(A) schematically represents a TBC system 90 of a type that benefits from the teachings of this invention. As shown, the coating system 90 includes a ceramic layer (thermal insulating layer) 96 bonded to the substrate 92 with an overlay bond coat 94. Optionally, the bond coat 94 may have ceramic dispersoids 95 of oxygen or other compounds dispersed at least substantially throughout as shown. To attain the dispersoids the ceramic is reactively created during or intermittently during the deposition process. The substrate 92 (e.g., combustion liner, etc.) is preferably a high-thermal conductivity, high-temperature material, such as copper, nickel or cobalt-base superalloy. The ceramic layer 96 is deposited by the desired deposition technique. Exemplary high melting temperature material for the ceramic layer (thermal insulating layer) 96 are, but not limited thereto, refractory metals Molydenum (Mo), Niobium (Nb), Tantalum (Ta), Titanium (Ti), or Tungsten (W), refractory metal alloys (e.g., but not limited thereto, intermetallics based upon these and other metals like Titanium alloys (such as TiAl, TiAl₃ etc.)), or carbides (such as, TiC, HfC, ZrC, TaC, W2C, SiC), or borides, or any alloys of the aforementioned refractory metals, carbides or borides. Additionally, oxides and nitrides may be suitable, for example, but not limited thereto, BN, MgO and BeO due to their very high temperature capability. The ceramic layer 96 is deposited to a thickness that is sufficient to provide the required thermal protection for the underlying substrate 92, generally on the order of about 50 to about 300 micrometers, or as desired or required. As mentioned throughout this document, in some embodiments the surface of the bond coat 94 may exist without an aluminum oxide surface layer (alumina scale) 98, or optionally in other embodiments the surface of the bond coat 94 may have minimal oxidization so as to form an aluminum oxide surface layer (alumina scale) 98 to which the ceramic layer 96 chemically bonds. It should be appreciated, that a TBC system can also be created with heavier layers of aluminum oxide surface layer (alumina scale) 98.

The present invention directed vapor deposition (DVD) apparatus and related method provide the technical basis for a small volume, low cost coating process capable of depositing the bond coat of a thermal barrier coating (TBC) system. DVD technology utilizes a trans-sonic gas stream to direct and transport a thermally evaporated vapor cloud to a component.

In an alternative embodiment, to endow the DVD process with the ability to create dense, crystalline coatings, a plasma activation unit is incorporated into the DVD system.

In an exemplary embodiment, Ti or Ti alloy (such as Ti-6-4) is applied over the substrate (typically copper) 92 to form the bond coat 94 with a ceramic thermal insulating layer 96 of zirconia, TiN, or TiC. The Ti alloy has melting points of about 1,700° C. Titanium has a high solubility for oxygen. Rather than immediately forming a scale (TGO) the Ti alloy will dissolve oxygen to stabilize the alpha phase. This raises the melting point slightly and can cause some embrittlement of the alloy. Titanium and its alloys have relatively low thermal conductivity. This is an advantage as the bond coat will provide some thermal barrier effect in the case of loss of the ceramic insulating layer.

In an exemplary embodiment, Zr or Zr alloys are applied over the substrate (typically copper) 92 to form the bond coat 94 with a ceramic thermal insulating layer of zirconia or ZrC. Zr behaves similar to Ti in many respects but has a higher melting point, about 1,852° C.

In an exemplary embodiment, Nb or Ta bond coat 94 applied over the substrate 92 or over an intermediate material (such at Ti) 89, as shown in FIG. 1(B) for. Elements Nb and Ta have melting points of 2,468° C. and 2,996° C., respectively. Their oxidation resistance is poor. These would only be suitable if non-oxidizing conditions prevailed. The top coat 96 could be either an oxide such as zirconia or a carbide (TaC).

In an exemplary embodiment, use of stainless steel as a bond coat 94 provides improvement over the MCrAlY type bond coats for a rocket engine or the like. Stainless steel has a higher melting point and does not have a low melting eutectic with copper. It forms a chromia scale instead of alumina (reference 98 representing either chromia or alumina scale). At the high pressures in a rocket engine, for example, chromia will not have the volatility problem encountered at lower pressures. Stainless steel may also be a good underlayer for other high temperature bond coat.

In an exemplary embodiment, intermetallics or any combination of intermettalics based on the above-mentioned materials—or other desired/required intermetallic compounds available for subject high temperature utility—are also possible bond coats with high temperature capability.

Additionally, if non-oxidizing conditions are present, then carbide ceramics can be deposited as a thermal insulating layer 96. Such carbide ceramics include, but limited thereto, SiC, TiC, ZrC , TaC or W₂C, which have extremely high melting points. Current TBCs use only oxide ceramics for insulation. The higher conductivity of the carbides would therefore be undesirable, but in the high heat flux environment of a rocket engine combustor, the higher conductivity is acceptable.

Additionally, other oxides and nitrides may be suitable, such as BN, MgO and BeO due to their very high temperature capability.

The present invention provides thermal protection coating method and resultant coating product for use is effective at extremely high temperatures and in high thermal gradients. An application of the present invention is for rocket engine combustion chamber liners, but not limited thereto. Other applications may include, for example, but not limited thereto: rocket engine combustion chamber and exhaust nozzle; rocket engine turbo pump; space re-entry vehicles; leading edge of Scram Jets and other hypersonic vehicles; thermal protection system f fusion reactors; TBC for future (or other applicable) gas turbine engines; solar powered rocked engines; heat exchangers; space and missile propulsion systems. It should appreciated that the present invention coating system can be utilized for applications with lower operating condition

The present invention coating has a unique combination of high temperature refractory materials, etc. and engineered microstructures that will allow it to survive under hostile conditions. The heat load on the structural members of the rocket engine, for example, can be greatly reduced with use of this coating, allowing rocket designers to improve engine performance and reduce life cycle costs, among other objectives and advantages.

The present invention provides thermal protection coating method and resultant product for use that can with stand high temperatures while preventing or inhibiting adverse spallation or otherwise degradation.

Still other embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of the appended claims. For example, regardless of the content of any portion (e.g., title, section, abstract, drawing figure, etc.) of this application, unless clearly specified to the contrary, there is no requirement for any particular described or illustrated activity or element, any particular sequence of such activities, or any particular interrelationship of such elements. Moreover, any activity can be repeated, any activity can be performed by multiple entities, and/or any element can be duplicated. Further, any activity or element can be excluded, the sequence of activities can vary, and/or the interrelationship of elements can vary. Accordingly, the descriptions and drawings are to be regarded as illustrative in nature, and not as restrictive.

The invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims rather than by the foregoing description, and all changes which come within the meaning and range of equivalency of the claims are therefore intended to be embraced herein.

We claim:

1. A method for forming a thermal barrier coating system, the method comprising:
presenting at least one substrate;
depositing at least one of Ti, Ti alloy, or any combination thereof to form a bond coat on at least a portion of at least one said substrate; and
depositing at least one of zirconia, zirconia alloy, TiN, TiC, TIN alloy, TiC alloy,or any combination thereof to form a deposition of a thermal-insulating layer on said bond coat.

2. The method of claim 1, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

3. The method of claim 1, wherein said deposition of said bond coat and thermal insulating layer is accomplished with a Directed Vapor Deposition (DVD).

4. The method of claim 3, wherein said DVD technique comprises:
said presenting of at least one of said substrate includes presenting said substrate to a chamber, wherein said chamber has an operating pressure ranging from about 0.1 to about 32,350 Pa;
presenting at least one additional evaporant sources to said chamber if desired;
presenting at least one carrier gas stream to said chamber;
impinging said desired evaporant source with at least one energetic beam in said chamber to generate an evaporated vapor flux impinged by said electron beam; and
deflecting at least one of said generated evaporated vapor flux by at least one of said carrier gas stream, wherein said evaporated vapor flux:
at least partially coats at least one said substrate to form said bond coat, and
at least partially coats said bond coat to form said thermal-insulating layer coat.

5. The method of claim 4, wherein said energetic beam comprises at least one of electron beam source, laser source, heat source, ion bombardment source, highly focused incoherent light source, microwave, radio frequency, EMF, or any energetic beam that break chemical bonds, or any combination thereof.

6. The method of claim 4, further comprising:
said chamber further includes a substrate bias system capable of applying a DC or alternating potential to at least one of said substrates;
impinging said at least one of said generated vapor flux and at least one of said carrier gas stream with a working gas generated by at least one hollow cathode arc plasma activation source to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

7. The method of claim 6, said generated electrons from said hollow cathode source is regulated for direction through variations in the quantity of working gas passing through said hollow cathode source.

8. The process of claim 6, wherein the distance between said cathode source and said generated evaporated vapor flux is regulated for ionization of the entire generated evaporated vapor flux.

9. The method of claim 4, further comprising at least one nozzle, wherein said at least one carrier gas stream is generated from said at least one nozzle and said at least one evaporant source is disposed in said at least one nozzle.

10. The method claim 9, wherein said evaporant retainer is a crucible.

11. The method of claim 4, further comprising:
said chamber further includes a substrate bias system capable of applying a DC or alternating potential to at least one of said substrates;
impinging said at least one of said generated vapor flux and at least one of said carrier gas stream with a low energy beam to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

12. A method for forming a thermal barrier coating system, the method comprising:
presenting at least one substrate;
depositing at least one of Zr, Zr Alloy, or combination thereof to form a bond coat on at least a portion of at least one said substrate; and
depositing at least one of ZrC or ZrC alloys, or any combination thereof to form a deposition of a thermal-insulating layer on said bond coat.

13. The method of claim 12, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

14. The method of claim 12, wherein said deposition of said bond coat and thermal insulating layer is accomplished with a directed vapor deposition (DVD).

15. A method for forming a thermal barrier coating system, the method comprising:
presenting at least one substrate;
depositing at least one of Nb, Nb alloy, Ta, Ta alloy or any combination thereof to form a bond coat on at least a portion of at least one said substrate; and
depositing at least one of as oxide or a carbide or any combination thereof to form a thermal-insulating layer on said bond coat.

16. The method of claim 15, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

17. The method of claim 15, wherein said deposition of said bond coat and thermal insulating layer is accomplished with a Directed Vapor Deposition (DVD).

18. The method of claim 15, wherein said thermal insulating layer comprises at least one of TaC or TaC alloys, or any combination thereof.

19. The method of claim 15, further comprising an intermediate layer between said bond coat and said thermal insulating layer.

20. The method of claim 19, wherein said intermediate layer comprises at least one of Ti or Ti alloy.

21. A method for forming a thermal barrier coating system, the method comprising:
presenting at least one substrate;
depositing at least one of stainless steel, composite of stainless steel, or alloy of stainless steel, or any combination thereof to form a bond coat on at least a portion of at least one said substrate; and
depositing a thermal-insulating layer on said bond coat.

22. The method of claim 21, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

23. The method of claim 21, wherein said deposition of said bond coat and thermal insulating layer is accomplished with a Directed Vapor Deposition (DVD).

24. The method of claim 21, wherein said thermal insulating layer comprises TiN, TiC, TiN alloy, TiC alloy, ZrC, ZrC alloys, Cu, Cu alloys, or any combination thereof.

25. A method for forming a thermal barrier coating system, the method comprising:
presenting at least one substrate;
depositing at least one intermetallic to form a bond coat on at least a portion of at least one said; and
depositing a thermal-insulating layer on said bond coat.

26. The method of claim 25, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

27. The method of claim 25, wherein said deposition of said bond coat and thermal insulating layer is accomplished with a Directed Vapor Deposition (DVD).

28. The method of claim 25, wherein said thermal insulating layer comprises TiN, TiC, TiN alloy, TiC alloy, ZrC, ZrC alloys, Cu, Cu alloys, or any combination thereof.

29. The method of claim 25, wherein said intermetallic material comprise at least one of intermetallic compound, or any combination of intermetallic compounds.

30. A deposition apparatus for forming a thermal barrier coating system, the apparatus comprising:
a housing, wherein at least one substrate is presented in said housing;
a deposition means for depositing at least one of Ti, Ti alloy, or any combination thereof to form a bond coat on at least a portion of at least one said substrate; and
said deposition means for depositing at least one of zirconia, zirconia alloy, TiN, TiC, TiN alloy, TiC or any combination thereof to form a deposition of a thermal-insulating layer on said bond coat.

31. The apparatus of claim 30, wherein said deposition means comprises:
at least one of directed vapor deposition (DVD) apparatus, chemical vapor deposition (CVD) apparatus, evaporation (thermal, RF, laser, or electron beam) apparatus, reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

32. The apparatus of claim 30, wherein said deposition means comprises:
a directed vapor deposition (DVD) apparatus.

33. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam, said energetic beam:
impinging at least one said evaporant source with at least one said energetic beam in said chamber to generate a bond coat evaporated vapor flux, said at least one evaporant source comprising at least one of Ti, Ti alloy, or any combination thereof to form, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, wherein said evaporant source for generating said thermal-insulating layer comprise at least one of zirconia, zirconia alloy, TiN, TiC, TiN alloy, TiC or combination thereof, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat.

34. The method of claim 33, wherein said energetic beam comprises at least one of electron beam source, electron gun source, laser source, heat source, ion bombardment source, highly focused incoherent light source, microwave, radio frequency, EMF, or any energetic beam system that breaks chemical bonds, or combination thereof.

35. The apparatus of claim 33, further comprising:
a substrate bias system capable of applying a DC or alternating potential to at least one of said substrates;
at least one hollow cathode arc source generating a low voltage beam, said at least one hollow cathode arc source:
impinging said at least one of said generated vapor flux and at least one of said carrier gas stream with a working gas generated by at least one said hollow cathode arc plasma activation source to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

36. The apparatus of claim 35, wherein said hollow cathode arc source comprises at least one cathode orifice wherein a predetermined selection of said cathode orifices are arranged in close proximity to the gas and vapor stream; and
an anode is arranged opposite of said cathode source wherein the gas and vapor stream is there between said cathode source and said anode.

37. The apparatus of claim 33, further comprising at least one nozzle, wherein said at least one carrier gas stream is generated from said at least one nozzle and said at least one evaporant source is disposed in said at least one nozzle, wherein said at least one said nozzle comprises:
at least one nozzle gap wherein said at least one said carrier gas flows there from; and
at least one evaporant retainer for retaining at least one said evaporant source, said evaporant retainer being at least substantially surrounded by at least one said nozzle gap.

38. The apparatus of claim 37, wherein said evaporant retainer is a crucible.

39. The apparatus of claim 33, further comprising:
a substrate bias system capable of applying a DC or alternating potential to at least one of said substrates;
at least one low energy beam source for generating a low voltage beam, said at least one low energy beam source:
impinging said at least one of said generated vapor flux and at least one of said carrier gas stream with a low energy beam to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

40. A deposition apparatus for forming a thermal barrier coating system, the apparatus comprising:
a housing, wherein at least one substrate is presented in said housing;
a deposition means, said deposition means for depositing at least one of Zr, Zr alloy, or combination thereof to form a bond coat on at least a portion of at least one said substrate; and
said deposition means for depositing at least one of ZrC, ZrC alloy, or any combination thereof to form a deposition of a thermal-insulating layer on said bond coat.

41. The apparatus of claim 40, wherein said deposition means comprises:
at least one of directed vapor deposition (DVD) apparatus, chemical vapor deposition (CVD) apparatus, evaporation (thermal, RF, laser, or electron beam) apparatus, reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

42. The apparatus of claim 41, wherein said deposition means comprises:
a directed vapor deposition (DVD) apparatus.

43. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam, said energetic beam:
impinging at least one said evaporant source with at least one said energetic beam in said chamber to generate a bond coat evaporated vapor flux, said at least one evaporant source comprising at least one of Zr, Zr alloy, or any combination thereof, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, wherein said evaporant source for generating said thermal-insulating layer comprise at least one of ZrC, ZrC alloys, or any combination thereof or any of their alloys, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat.

44. A deposition apparatus for forming a thermal barrier coating system, the apparatus comprising:
a depositing means, said depositing means for depositing a at least one of Nb, Nb alloy, Ta, Ta alloy or any combination thereof to form bond coat on at least a portion of at least one said substrate; and
said depositing means for depositing at least one of an oxide or a carbide to form a thermal-insulating layer.

45. The apparatus of claim 44, wherein said deposition means comprises:
at least one of directed vapor deposition (DVD) apparatus, chemical vapor deposition (CVD) apparatus, evaporation (thermal, RF, laser, or electron beam) apparatus, reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

46. The apparatus of claim 44, wherein said deposition means comprises:
a directed vapor deposition (DVD) apparatus.

47. The apparatus of claim 44, wherein said thermal insulating layer comprises at least one of TaC or TaC alloys, or any combination thereof.

48. The apparatus of claim 44, said depositing means for depositing an intermediate layer between said bond coat and said thermal insulating layer.

49. The method of claim 48, wherein said intermediate layer comprises at least one of Ti or Ti alloy.

50. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam, said energetic beam:
impinging at least one said evaporant source with at least one said energetic beam in said chamber to generate a bond coat evaporated vapor flux, said at least one evaporant source comprising at least one of Nb, Nb alloy, Ta, Ta alloy or any combination thereof, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, wherein said evaporant source for generating said thermal-insulating layer comprises at least one of an oxide or carbide, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat.

51. A deposition apparatus for forming a thermal barrier coating system, the apparatus comprising:
a depositing means, said depositing means for depositing at least one of stainless steel, composite of stainless steel, or alloy of stainless steel, or any combination thereof to form a bond coat on at least a portion of at least one said substrate; and
said depositing means for depositing a thermal-insulating layer.

52. The apparatus of claim 51, wherein said deposition means comprises:
at least one of directed vapor deposition (DVD) apparatus, chemical vapor deposition (CVD) apparatus, evaporation (thermal, RF, laser, or electron beam) apparatus reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

53. The apparatus of claim 51, wherein said deposition means comprises:
a directed vapor deposition (DVD) apparatus.

54. The apparatus of claim 51, wherein said thermal insulating layer comprises TiN, TiC, TiN alloy, TiC alloy, ZrC, ZrC alloys, Cu, Cu alloys, or any combination thereof.

55. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam, said energetic beam:
impinging at least one said evaporant source with at least one said energetic beam in said chamber to generate a bond coat evaporated vapor flux, wherein said evaporant source comprises at least one of stainless steel, composite of stainless steel, or alloy of stainless steel, or any combination thereof, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat.

56. A deposition apparatus for forming a thermal barrier coating system, the apparatus comprising:
a depositing means, said depositing means for depositing at least one of intermetallic; and
said depositing means for depositing a thermal-insulating layer.

57. The apparatus of claim 56, wherein said deposition means comprises:
at least one of directed vapor deposition (DVD) apparatus, chemical vapor deposition (CVD) apparatus, evaporation (thermal, RF, laser, or electron beam) apparatus, reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

58. The apparatus of claim 56, wherein said deposition means comprises:
a directed vapor deposition (DVD) apparatus.

59. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam, said energetic beam:
impinging at least one said evaporant source with at least one said energetic beam in said chamber to generate a bond coat evaporated vapor flux, wherein said evaporant source comprises at least one intermetallic material, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat.

60. A coating system on a substrate, the coating system comprising:
a bond coat in communication with at least a portion of said substrate, said bond coat comprising least one of Ti, Ti alloy, or any combination thereof; and
a thermal-insulating layer in communication with at least a portion of said bond coat, said thermal-insulating layer comprising at least one of zirconia, zirconia alloy, TiN, TiC, TiN alloy, TiC alloy or any combination thereof.

61. A coating system on a substrate, the coating system comprising:
a bond coat in communication with at least a portion of said substrate, said bond coat comprising least one of Zr, Zr Alloy, or any combination thereof; and
a thermal-insulating layer in communication with at least a portion of said bond coat, said thermal-insulating layer comprising at least one of ZrC, ZrC alloys or any combination thereof.

62. A coating system on a substrate, the coating system comprising:
a bond coat in communication with at least a portion of said substrate, said bond coat comprising least one of Nb, Nb alloy, Ta, Ta alloy, or any combination thereof; and
a thermal-insulating layer comprised of at least one of an oxide or a carbide, or combination thereof, in communication with at least a portion of said bond coat.

63. The system of claim 62, wherein said thermal insulating layer comprises at least one of TaC or TaC alloys, or any combination thereof.

64. The system of claim 62, further comprising an intermediate layer disposed between said bond coat and said thermal insulating layer.

65. The system of claim 64, wherein said intermediate layer comprises at least one of Ti or Ti alloy.

66. A coating system on a substrate, the coating system comprising:
a bond coat in communication with at least a portion of said substrate, said bond coat comprising least one of at least one of stainless steel, composite of stainless steel, or alloy of stainless steel, or any combination thereof; and
a thermal-insulating layer in communication with at least a portion of said bond coat.

67. The system of claim 66, wherein said thermal insulating layer comprises TiN, TiC, TiN alloy, TiC alloy, ZrC, ZrC alloys, Cu, Cu alloys, or any combination thereof.

68. A coating system on a substrate, the coating system comprising:
a bond coat in communication with at least a portion of said substrate, said bond coat comprising intermetallic material; and
a thermal-insulating layer in communication with at least a portion of said bond coat.

69. The method of claim 68, wherein said thermal insulating layer comprises TiN, TiC, TIN alloy, TiC alloy, ZrC, ZrC alloys, Cu, Cu alloys, or any combination thereof.

70. The method of claim 68, wherein said intermetallic material comprise at least one of intermetallic compound, or any combination of intermetallic compounds.

71. The system of any one of claims 60, 61, 62, 66, or 68, wherein said substrate is at least one of:
rocket engine component, space reentry vehicle component, scram jet component, hypersonic vehicle component, fusion reactor component, gas turbine engine component, diesel engine component, turbine blade, or airfoil.

72. The system of any one of claims 60, 61, 62, 66, or 68, wherein said deposition technique of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

73. The system of any one of claims 60, 61, 62, 66, or 68, wherein said deposition technique of said bond coat and thermal insulating layer is accomplished with a directed vapor deposition (DVD).
